(19) United States
(12) Patent Application Publication
(10) Pub. No.: US 2004/0190232 A1
(43) Pub. Date: Sep. 30, 2004

(54) Case for programmable logic controller (PLC)

(75) Inventors: Chin-Jui Chang, Taoyuan (TW); Thomas Chiang, Taoyuan (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: Delta Electronics, Inc., Taoyuan (TW)

(21) Appl. No.: 10/645,428

(22) Filed: Aug. 21, 2003

(30) Foreign Application Priority Data
Mar. 31, 2003 (TW) 092205025

(51) Int. Cl. H05K 5/00

(52) U.S. Cl. 361/679

(57) ABSTRACT

The present invention provides a case having the function of storing a signal line, and more particularly to a case of programmable logic controller having the function of storing a signal line. The case having the function of storing a signal line includes a front panel, a back panel, a lateral panel, and a base. An opening is disposed on anyone panel to store an over-length portion of the signal line for making the electronic device adjacent to the expander.

### FIELD OF THE INVENTION

This invention relates to a case for storing a signal line, and more particularly to a case of a programmable logic controller (PLC) for storing a signal line.

### BACKGROUND OF THE INVENTION

The fast technology development makes more competitions in the industries. For the purpose of making the products with more varieties, high quality and low cost, the demand of automation becomes very important. And the Programmable Logic Controller (PLC) is the best solution for the automation. Nowadays, a programmable logic controller mostly accomplishes the automation of the manufactory process. The programmable logic controller is basically a small computer designed specifically for the process control system. The user designs and writes the programs into the memory. Then CPU processes the input signals from the buttons, sensors or switches through the control unit in the program and then output the signals to the outside loads like indicator, etc. Sometimes, depending on the user's need, the output signals can feedback as the input to control other output devices.

PLC system has the following features: (1) Central management with separate controls: Based on the characteristics and needs, the PLC have different control groups for different processes. The operations and maintains won't be affected if one control group is malfunctioned. They can be separately operated to reduce the risk of shutting down the whole system. The different groups of the controllers are connected through the network. This will speed up the information collection and the data are easily uploaded to the main computer to centrally control all the information. (2) Flexible design and easy expansion: Use the main-stream small or medium controllers to plan separately, so it can be adjusted whenever and wherever the system's demand and scale are changed. It is very flexibly extended and expanded of the factory building. So it will help to reflect the changes of the market quickly and increase the capabilities of competition. (3) Simple operation and fast maintenance: Touch-controlled screen operation is user-friendly. And the complete menu for the operation and the warnings of abnormal situations makes the system simple to operate, easy to eliminate the abnormal conditions and maintain quickly.

The stability, flexibility, control modules of varieties of signals and capabilities of network communication expansion are mostly appreciated by the users. The priority for the factory to choose the controllers is stability, cost and functions, maintenance, extension, etc. Among the controllers, PLC is easily expanded. Based on different demands, different ways are used for the expansion of PLC to increase the functions of the programmable control. When the PLC is extended, the bus is used to connect the extender. When the main machine is connected to the expender, a gap between them is produced caused from the over-length portion of the bus. Besides the machines couldn't stay closely, it also wastes the space and looks disorganized. 100051 Because of the technical defects according to prior arts, the applicant keeps on carving unflaggingly to develop a “improved case for programmable logic controller (PLC)” through wholehearted experience and research.

### SUMMARY OF THE INVENTION

It is an object of the present invention to provide an improved case of an electronic device, especially a programmable logic controller, for storing an over-length portion of the signal line efficiently, thoroughly eliminates the disadvantage on the space management for the connecting signal line of the prior art.

It is another object to provide an improved case of an electronic device, especially a programmable logic controller, for storing an over-length portion of the signal line. This can make an electronic device closely next to the other electronic device while connecting via a signal line. Therefore, the space will become in order and pleasing to the eye.

In accordance with the present invention is to provide a case having a function of storing a bus for containing an electronic device, including a front panel, a back panel, a lateral panel connected to the front panel and the back panel, and a base, wherein an opening is disposed on any panel of the case to store an over-length portion of the bus for making said electronic device adjacent to an expander.

Preferably, the opening is disposed on one of the front panel, the lateral panel and the back panel.

Preferably, the opening appearance is one of a square, a rectangle and a circle.

Preferably, the electronic device is one of a programmable logic controller (PLC), a personal computer (PC) and an industrial computer.

Preferably, the industrial computer is a 1 U server.

Preferably, the expander is one of a programmable logic controller (PLC), a personal computer (PC) and an industrial computer.

Preferably, the industrial computer is a 1 U server.

Preferably, the case is a rectangular case.

Preferably, the case further includes a port for connecting the bus.

Preferably, the opening and the port are disposed on the same panel.

Preferably, the case further includes a disassembliable upper cover.

In accordance with the present invention is to provide a case having a function of storing a signal line for containing an electronic device, including a front panel, a back panel, a lateral panel connected to the front panel and the back panel, and a base, wherein an opening is disposed on any panel of the case to store an over-length portion of the signal line for making the electronic device adjacent to an expander.

Preferably, the case further includes a port for connecting a signal line.

Preferably, the signal line is a bus.

Preferably, the signal line is a network cable.

Preferably, the signal line is an optical fiber cable.

The present invention may best be understood through the following description with reference to the accompanying drawings, in which:

### BRIEF DESCRIPTION OF THE DRAWINGS

FIG. 1 shows 3-dimension view of the PLC of the prior art;

FIG. 2 shows the 3-dimentional view of the case structure of the PLC according to a preferred embodiment of the present invention;

FIG. 3 shows the 3-dimentional view of the case structure of the PLC according to a preferred embodiment of the present invention; and

FIG. 4 shows the schematic view illustrating the connection between two PLCs according to a preferred embodiment of the present invention.

### DETAILED DESCRIPTION OF THE PREFERRED EMBODIMENT

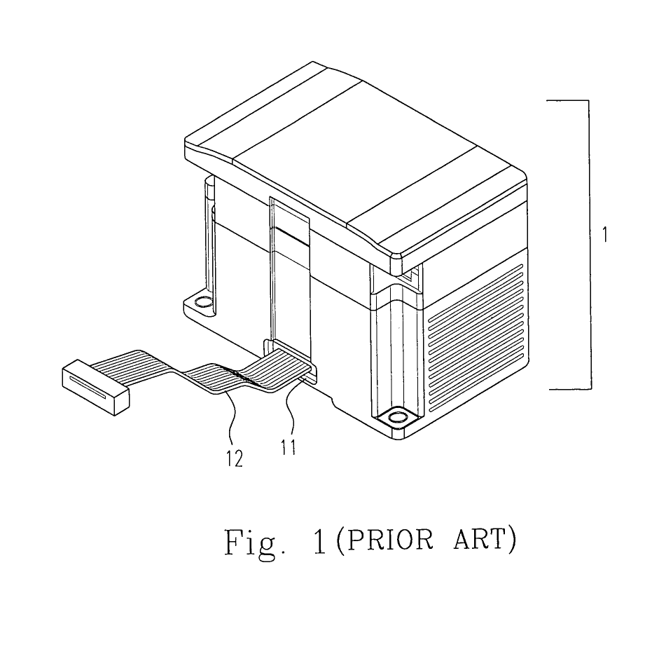

Please refer to FIG. 1, which shows the 3-dimension view of the PLC of the prior art. The main structure is the rectangular main body 1. A connecting port 11 is disposed on the back panel of this rectangular main body 1 for connecting to outside. The connecting port 11 connects to another PLC by the bus 12. As the PLC main body 1 of the prior art is a closed design, the bus 12 hangs outside between two PLCs. As the bus 12 is stiffer than the other types of wires, the long bus 12 wastes lots of space while connecting.

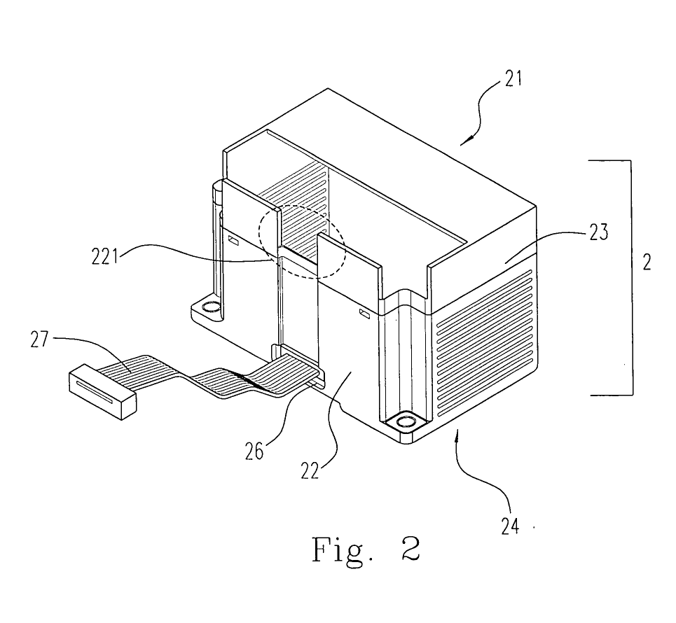

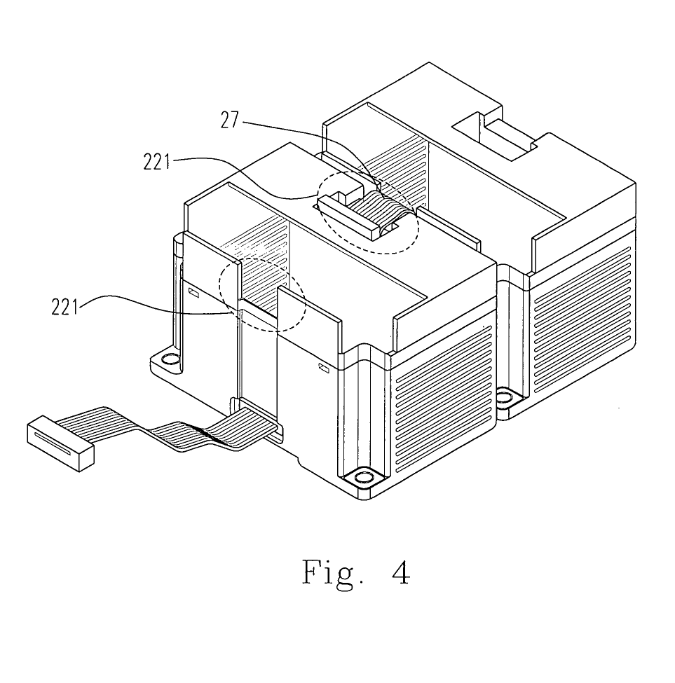

Please refer to FIG. 2 and FIG. 4. FIG. 2 shows the 3-dimentional view of the case structure of the PLC according to a preferred embodiment of the present invention. The structure includes a front panel 21, a back panel 22, two lateral panels, a base and an upper cover 25 to form the rectangular main body 2. The back panel 22 has a rectangular opening 221. As we know, we can put one or more circuit boards (not shown) in the body of the PLC. For the strong capability of extension of PLC, the connecting port 26 is always set on one panel while expanding. In this example, the connecting port 26 is placed on the back panel 22. The bus 27 is used to connect the PLC and the other expand-machine. As the design of the rectangular opening 221 on the back panel 22, the bus 27 can be put into the PLC main body 2 through the rectangular opening 221 while connecting the PLCs as shown in FIG. 4. There won't be any bus 27 in between PLCs, so they can be placed next to each other closely to save space and look organized.

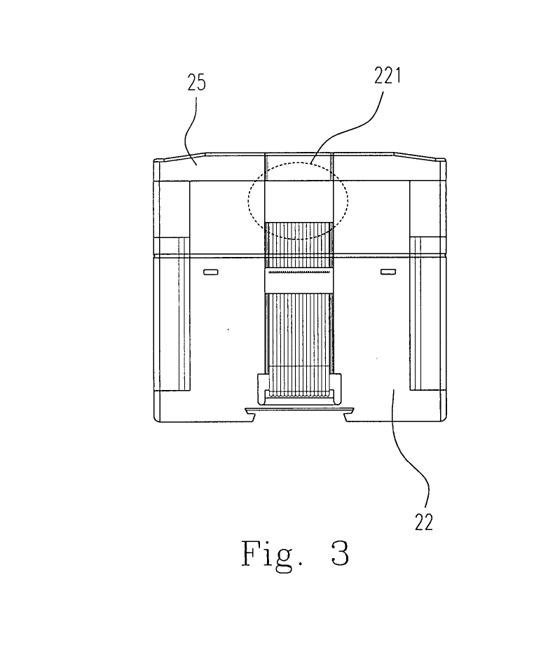

Please refer to FIG. 3, which shows the back view of the case structure of the PLC according to a preferred embodiment of the present invention. In the application of the PLC, Personal Computer (PC) can be used for monitoring and controlling process. Through the interface circuit, PLC can be connected to PC. Via setting the communication parameters on both sides, internal programs on the PLC can be accessed from the PC. To connect both, buses will be used such as the RS232. The bus 27 is stored in the PLC main body through the rectangular opening 221 on the back panel 22 so as to save space and keep the office in order.

In these years, the Ethernet and Internet are the trend for industry automation. The other preferred embodiment of the present invention is the air condition internet-controlled system. The connecting port on the back panel of the PLC is connected to the switch of the main machine of air condition by a cable. At the same time, the connecting port on the other panel or the same panel of the PLC is connected to the computer through the network cable. Such setting will let the operator to control the machines far away. For the cables described above, this invention will make the cables invisible. If there are more than two connecting ports, no matters they are located in the same or different panels depending on the user's need or design, the cables can be either hided in one or more rectangular or round openings respectively. Certainly, we can make a proper design according to the actual condition.

A preferred embodiment of the present invention is the high-density 1 U server system. As multiple 1 U servers located on the same counter, it is the important task to make the cables in good control. To collect all the tables in the opening on the panel of the connector on the servers solves this problem and achieves the task.

Another preferred embodiment of the present invention shows in the semiconductor foundries using PLC for the process control. For easy management, multiple PLCs are stacked to control multiple processes. PLCs are connected in the ways depending on the users' need, for example, a bus or a fiber cable or a network cable. Then the Ethernet is used to connect all the PLCs to the PC, which controls and monitors all the processes. Again, the stacked PLCs produce the problem of the cables management and also the space control. The idea of this invention, having an opening on the panel of the PLC for storing the cables, can solve the problem effectively.

To sum up all the above, this invention, providing the specific PLC case to store the signal lines, thoroughly eliminates the disadvantage on the space management for the connecting cables of the prior art. So the present invention is creative, original and advanced. Besides meeting the requirement for the current industries, the present invention also provides the new effective method to eliminate the disadvantage of the prior art. So the present invention really has the value of the practical development.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A case having a function of storing a bus for containing an electronic device, comprising:
a front panel;
a back panel;
a lateral panel connected to said front panel and said back panel; and
a base,
wherein an opening is disposed on any said panel to store an over-length portion of said bus for making said electronic device adjacent to an expander.

2. The case as claimed in claim 1, wherein said opening is disposed on one of said front panel, said lateral panel and said back panel.

3. The case as claimed in claim 1, wherein said opening appearance is one of a square, a rectangle and a circle.

4. The case as claimed in claim 1, wherein said electronic device is one of a programmable logic controller (PLC), a personal computer (PC) and an industrial computer.

5. The case as claimed in claim 4, wherein said industrial computer is a 1 U server.

6. The case as claimed in claim 1, wherein said expander is one of a programmable logic controller (PLC), a personal computer (PC) and an industrial computer.

7. The case as claimed in claim 6, wherein said industrial computer is a 1 U server.

8. The case as claimed in claim 1, wherein said case is a rectangular case.

9. The case as claimed in claim 1 further comprising a port for connecting said bus.

10. The case as claimed in claim 1, wherein said opening and said port are disposed on same said panel.

11. The case as claimed in claim 1 further comprising a disassembliable upper cover.

12. A case having a function of storing a signal line for containing an electronic device, comprising:
a front panel;
a back panel;
a lateral panel connected to said front panel and said back panel; and
a base,
wherein an opening is disposed on any said panel to store an over-length portion of said signal line for making said electronic device adjacent to an expander.

13. The case as claimed in claim 12 further comprising a port for connecting said signal line.

14. The case as claimed in claim 12, wherein said signal line is a bus.

15. The case as claimed in claim 12, wherein said signal line is a network cable.

16. The case as claimed in claim 12, wherein said signal line is an optical fiber cable.
